(19) United States
(12) Patent Application Publication
(10) Pub. No.: US 2016/0103162 A1
(43) Pub. Date: Apr. 14, 2016

(54) VEHICLE POWER FLOW MONITORING

(71) Applicant: The Boeing Company, Chicago, IL (US)

(72) Inventors: Robab Safa-Bakhsh, Ambler, PA (US); Bruce D. Harmon, Vineland, NJ (US)

(21) Appl. No.: 14/513,472

(22) Filed: Oct. 14, 2014

(51) Int. Cl. G01R 21/133; G01M 17/007; B60R 16/03

(52) U.S. Cl. CPC G01R 21/133; B60R 16/03; G01M 17/007

(57) ABSTRACT

A vehicle electrical power flow monitoring system including at least one channel power monitor node corresponding to a respective power distribution channel of a vehicle electrical power system, the at least one channel power monitor node being common to at least another different vehicle monitoring system, and at least one data acquisition node within each power distribution channel, each of the at least one data acquisition node being common to the at least another different vehicle monitoring system and communicably connected to a respective channel power monitor node, and wherein the at least one channel power monitor node is configured to receive electrical power flow data from a corresponding data acquisition node and determine an operating state of the vehicle electrical power system based on the electrical power flow data.

### BACKGROUND

Generally, power flow monitoring within a vehicle is performed with a dedicated system that includes dedicated sensors, hardware and wiring. Data is acquired from the dedicated sensors to monitor, for example, current within the power system and to provide information to a user regarding the power flow within the power system.

As may be realized, the power distribution system includes wiring that spans substantially across a length of a vehicle in which the power distribution system is located. Conventional current load and power flow monitoring systems generally require extensive wiring and dedicated monitoring systems and hardware that add weight and cost to the power flow monitoring system and hence add weight and cost to the vehicle.

### SUMMARY

Accordingly, apparatus and method, intended to address the above-identified concerns, would find utility.

One example of the present disclosure relates to a vehicle electrical power flow monitoring system including at least one channel power monitor node corresponding to a respective power distribution channel of a vehicle electrical power system, the at least one channel power monitor node being common to at least another different vehicle monitoring system, and at least one data acquisition node within each power distribution channel, each of the at least one data acquisition node being common to the at least another different vehicle monitoring system and communicably connected to a respective channel power monitor node, and wherein the at least one channel power monitor node is configured to receive electrical power flow data from a corresponding data acquisition node and determine an operating state of the vehicle electrical power system based on the electrical power flow data.

One example of the present disclosure relates to a vehicle electrical power flow monitoring system including a user interface, a parasitic power flow monitor having a hierarchical architecture and including at least one channel power monitor node corresponding to a respective power distribution channel of a vehicle electrical power system, the at least one channel power monitor node being common to at least another different vehicle monitoring system, and a plurality of acquisition nodes within each power distribution channel, each of the plurality of data acquisition nodes being common to the at least another different vehicle monitoring system and communicably connected to a corresponding channel power monitor node, and wherein the at least one channel power monitor node is configured to receive electrical power flow data from respective ones of the at least one data acquisition node and determine an operating state of the vehicle electrical power system based on the electrical power flow data.

One example of the present disclosure relates to a method including sending electrical power flow data from at least one data acquisition node, that is common to a plurality of vehicle monitoring systems, distributed throughout a power distribution channel of an electrical power system of a vehicle, to a respective channel power monitor node that is common to a plurality of vehicle monitoring systems, and determining, with at least one channel power monitor node, an operating state of the electrical power system based on the electrical power flow data.

### BRIEF DESCRIPTION OF THE DRAWINGS

Having thus described examples of the disclosure in general terms, reference will now be made to the accompanying drawings, which are not necessarily drawn to scale, and wherein like reference characters designate the same or similar parts throughout the several views, and wherein:

FIG. 1 is a block diagram of a vehicle electrical power flow monitoring system, according to one aspect of the present disclosure;

FIG. 2 is a schematic illustration of one channel of the power flow monitoring system, according to one aspect of the disclosure;

FIG. 3 is a schematic illustration of a portion of the power flow monitoring system, showing multiple channels according to one aspect of the disclosure;

FIG. 4 is a flow diagram for monitoring electrical power flow within a vehicle according to one aspect of the disclosure;

FIG. 5 is a flow diagram of aircraft production and service methodology; and

FIG. 6 is a schematic illustration of an aircraft including distributed vehicle systems.

In the block diagram(s) referred to above, solid lines, if any, connecting various elements and/or components may represent mechanical, electrical, fluid, optical, electromagnetic and other couplings and/or combinations thereof. As used herein, “coupled” means associated directly as well as indirectly. For example, a member A may be directly associated with a member B, or may be indirectly associated therewith, e.g., via another member C. Couplings other than those depicted in the block diagrams may also exist. Dashed lines, if any, connecting the various elements and/or components represent couplings similar in function and purpose to those represented by solid lines; however, couplings represented by the dashed lines may either be selectively provided or may relate to alternative or optional aspects of the disclosure. Likewise, elements and/or components, if any, represented with dashed lines, indicate alternative or optional aspects of the disclosure. Environmental elements, if any, are represented with dotted lines.

In the block diagram(s) referred to above, the blocks may also represent operations and/or portions thereof. Lines connecting the various blocks do not imply any particular order or dependency of the operations or portions thereof.

### DETAILED DESCRIPTION

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Reference herein to “one example” or “one aspect” means that one or more feature, structure, or characteristic described in connection with the example or aspect is included in at least one implementation. The phrase “one example” or “one aspect” in various places in the specification may or may not be referring to the same example or aspect.

Unless otherwise indicated, the terms “first,” “second,” “third,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

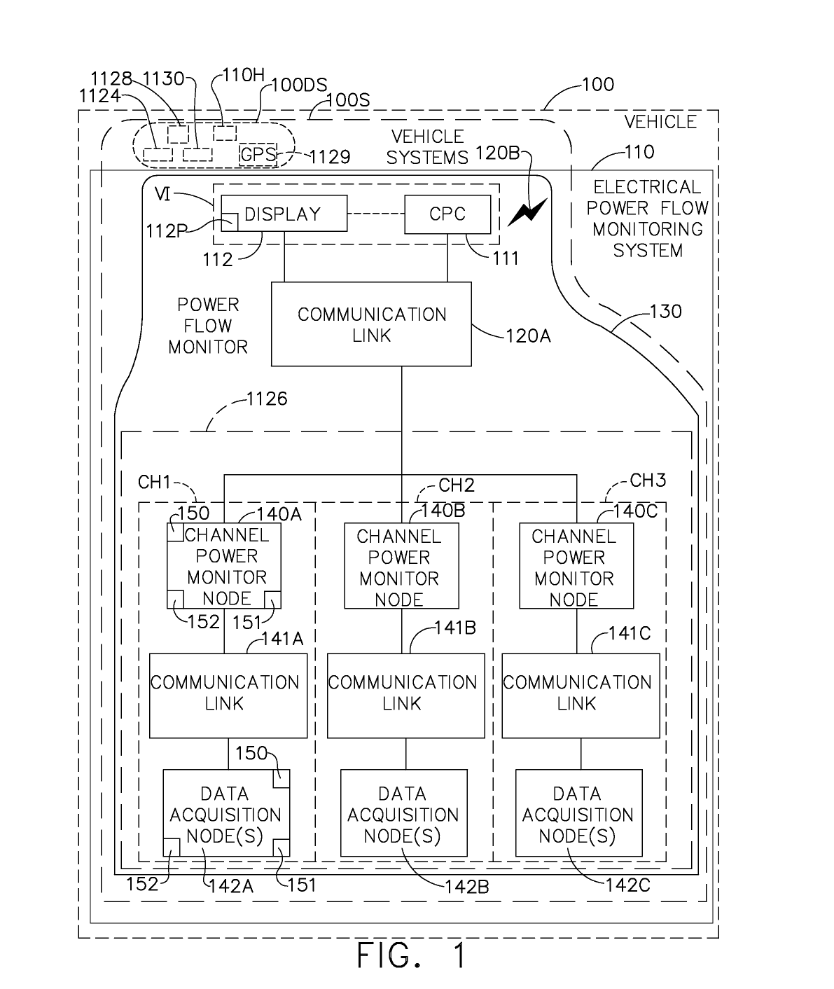

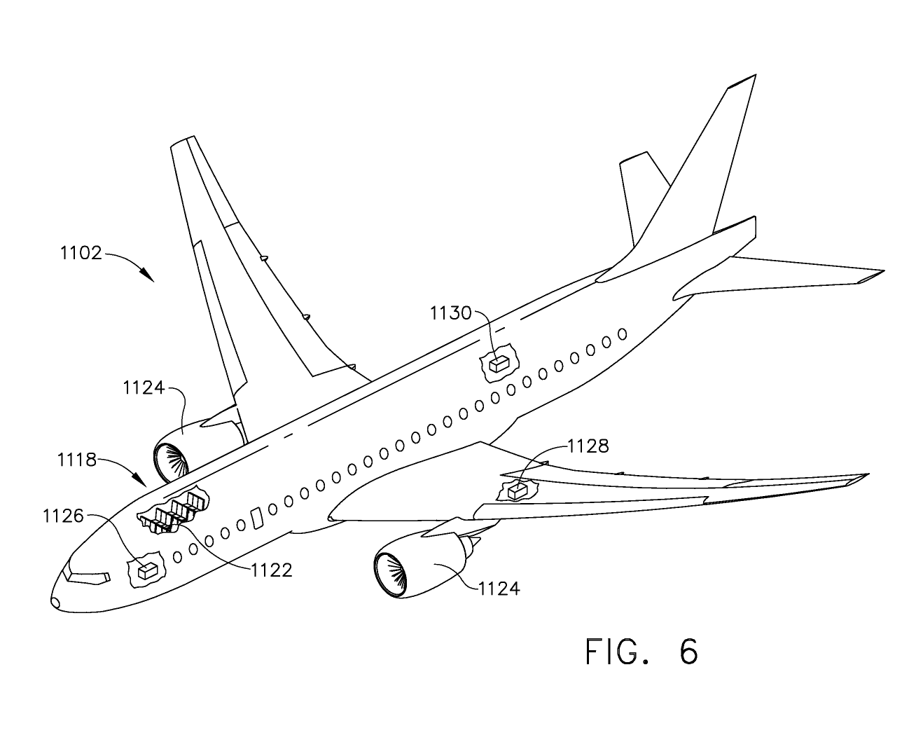

Referring to FIG. 1, the aspects of a vehicle electrical power flow monitoring system 110 described herein provide active monitoring of and an accurate measure of, for example, load, power flow and distribution in a vehicle electrical power system 1126 (FIG. 6) with minimal cost and weight penalty. For example, as will be described in greater detail below, the components of the vehicle electrical power flow monitoring system 110 are in communication with each other through a networked architecture that in one aspect is a hierarchical networked architecture while in other aspects any suitable network architecture may be employed. In one aspect, the vehicle electrical power flow monitoring system 110 is a parasitic system where the term parasitic means that the vehicle electrical power flow monitoring system 110 is interconnected with at least one different/preexisting vehicle monitoring systems 100DS (such as for example, a propulsion system 1124, an electrical power system 1126, a hydraulic system 1128, an environmental system 1130) so as to use (i.e. leverages) the inputs, outputs, power supplies, existing/available communication links, sensors and data (e.g. sensors used by and data obtained from other systems) of the different/preexisting vehicle monitoring systems 100DS in the vehicle electrical power system 1126 so that the various vehicle monitoring systems are tied together into a common monitoring system having a common processor effecting vehicle power flow monitoring and effecting the minimization of cost as well as a reduction of weight (e.g. the communication links, sensors and data are common between the vehicle electrical power flow monitoring system 110 and other different vehicle monitoring systems 100DS of the vehicle 100). As will also be described herein, the aspects of the disclosure enable power management and automatic power shedding resulting in reduced work load of a vehicle operator.

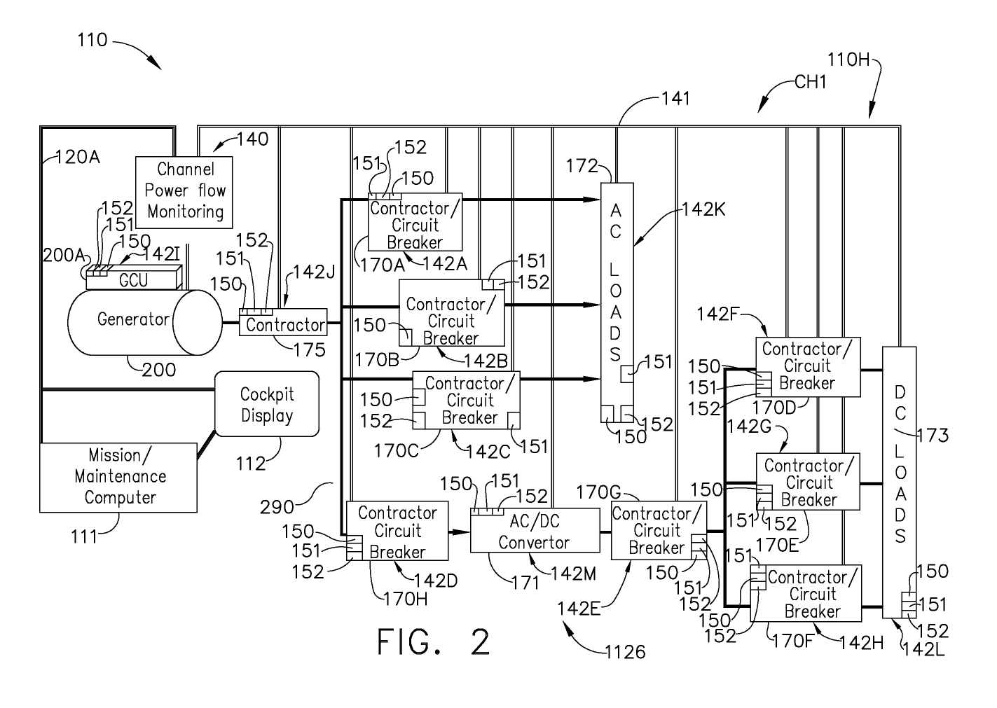

As can be seen in FIG. 1, the vehicle electrical power flow monitoring system 110 is a hierarchically distributed networked system that includes a power flow monitor 130 having one or more distributed channel power monitor (e.g. branch) node 140A-140C and one or more distributed data acquisition (e.g. remote) node 142A-142C that are time synchronized (e.g., via a common clock signal common to all components of the vehicle 100 where the time synchronization is affected by reading the vehicle time on, for example the serial link or through a global positioning system (GPS) 1129 accessible by or included within the vehicle systems). Each data acquisition node 142A-142C includes (e.g. is formed by) a component of, for example, the vehicle electrical power system 1126 (as will be described below), data acquisition/memory 151 and a processor(s) 152. As used herein the term “distributed” refers to the placement/networking of one or more components throughout a vehicle. In one aspect, there is a channel power monitor node 140A-140C for each channel CH1-CH3 of the vehicle electrical power system 1126 where each channel CH1-CH3 corresponds to at least one power generator 200/generator control unit GCU 200A (FIG. 2) and the electrical components/data acquisition node(s) 142A-142C connected to the at least one power generator 200/generator control unit GCU 200A. As will be described in greater detail below, each of the one or more data acquisition node 142A-142C is configured to collect and/or process data related to the electrical power system at a predetermined location and communicate one or more of raw data or processed data to the one or more channel power monitor node 140A-140C through any suitable wired and/or wireless networked communication link 141A-141C such as, for example, one or more serial links (e.g. ARINC 429, CAN BUS, Ethernet, wireless, etc.) that include, for exemplary purposes, a physical layer and a communication layer for communicating vehicle electrical power system data/information in a time synchronous manner to, for example, a respective channel power monitor node 140A-140C. In one aspect, the data acquisition nodes 142A-142C are included within or associated with a device of the vehicle electrical system 1126. For example, the data acquisition nodes 140A-140C are included within or associated with one or more of any suitable line replaceable unit, a contactor, a load controller, a load, and any other suitable component of the vehicle electrical system 1126 so as to be common with a plurality of vehicle monitoring systems. As may be realized, in one aspect, each electrical component of the vehicle electrical system 1126 is a “smart” component having sensors, memory and processor(s) for collecting and processing electrical power flow data obtained from the component at a location of the component so as to form a respective data acquisition node 140A-140C. The data acquisition nodes 140A-140C may receive or generate any suitable sensor data associated with the respective component of the vehicle electrical system 1126 such as, but not limited to, a temperature, a voltage, a current, and/or another environmental or operating parameter associated with the electrical component.

Each of the channel power monitor nodes 140A-140C is communicably coupled to a vehicle system 100S through any suitable communication link 120A (substantially similar to that described above with respect to communication link 141A-141C) which, in one aspect is a vehicle communication bus that uses any suitable protocol to facilitate communication between each channel power monitor node 140A-140C, the data acquisition nodes 142A-142M, and the vehicle system 100S. In one aspect the vehicle system includes a vehicle central data collection, processing, and reporting unit that is configured to collect, process, and report vehicle system status information. The vehicle system 100S, in one aspect is a dedicated system, while in other aspects the vehicle system 100S is a shared system supporting other vehicle system functionalities. For example, in one aspect the vehicle system 100S includes one or more of a vehicle power flow monitoring system 110, a vehicle health management system, a mission system (e.g., a mission computer), a maintenance system (e.g., a maintenance data loader system), a ground based computer, a support equipment device, data downloader hardware where the data acquisition nodes 142A-142C, power channel monitor nodes 140A-140C and communication links 120A, 141A are common to more than one of these vehicle systems.

In one aspect the vehicle electrical power flow monitoring system 110 includes, in one example, as a shared part of the vehicle system 100S, a user interface UI including at least one central processing computer (CPC) 111 (which in one aspect is a vehicle data acquisition, processing and reporting unit such as, for example, one or more of a mission/maintenance computer, central maintenance computer and an onboard file server of the vehicle 100, where the vehicle is any suitable aerospace, maritime, or ground based vehicle) and at least one display 112 (which in one aspect is a cockpit display) communicably coupled to the central processing computer 111. The central processing computer 111 is any suitable controller including hardware and software configured to receive the vehicle electrical power system data/information from the one or more power channel monitor nodes 140A-140C and, if needed, process the data/information for communication to the display 112. In one aspect the display 112 is connected to the central processing computer 111 through any suitable networked communication link 120A (which in one aspect, as noted herein, is a preexisting communication link common to more than one system of the vehicle 100) while in other aspects the display 112 is connected directly to or is integrated with the central processing computer 111. In one aspect the display 112 includes a display processor 112P and data obtained, as described herein, pertaining to the power flow monitoring of the vehicle 100 can be sent to one or more of the display processor 112P and the central processing computer 111 from the power flow monitor 130 depending on, for example, an architecture of the vehicle systems. In one aspect the user interface UI is a graphical user interface configured to present graphical representation of the vehicle electrical power flow data as described herein so that system status information is conveyed to an operator of the vehicle 100, to a maintenance technician (e.g., a ground crew member) associated with the vehicle, to a diagnostic professional associated with the vehicle 100, or to one or more off-board systems.

In one aspect the networked communication link 120A is substantially similar to the networked communication link 141A-141C described above so that the data/information from the one or more channel power monitor node 140A-140C is communicated to the central processing computer 111 where the data/information is received, and if needed, further processed for presentation to an operator of the vehicle 100 and/or downloaded (e.g. through any suitable wired, removable storage media, or wireless communication link 120B) to any suitable off-board or otherwise ground based monitoring and/or maintenance system. The one or more channel power monitor node 140A-140C is connected to one or more of the central processing computer 111 and display 112 through the networked communication link 120A.

The one or more channel power monitor node 140A-140C includes any suitable hardware (including, such as e.g. a suitable processor and memory) and software configured to collect data related to the vehicle electrical power system 1126 from the one or more data acquisition nodes 142A-142C. The hardware and software of the one or more channel power monitor node 140A-140C is also configured to collect power flow information from a respective power generator 200/generator control unit GCU 200A (FIG. 2). In one aspect the one or more channel power monitor node 140A-140C processes information obtained/received from the one or more data acquisition node 142A-142C and communicates one or more attributes of the electrical power flow within the respective channel CH1-CH3 to the central processing computer 111. In other aspects, the one or more channel power monitor node 140A-140C communicates raw information/data (e.g. information that is not processed by the channel power monitor node 140A-140C) obtained/received from the one or more data acquisition node 142A-142C to the central processing computer 111 where the central processing computer 111 processes the raw information and determines one or more attributes of the electrical power flow within the channel CH1-CH3 corresponding to the channel power monitor node 140A-140C from which the raw information was received. In one aspect the central processing computer 111 communicates the attributes of the electrical power flow to the display 112 where a visual/graphical representation of the attributes are available for viewing by, for example, an operator or crew member of the vehicle 100. Suitable examples of the attributes made available for viewing include, but are not limited to, real time amplitudes of current and voltage, phase angles, crest factor, distortion factor, voltage modulation, distortion spectrum, DC content on AC waveforms, DC waveform ripple, and other suitable power quality attributes as well as a status of the one or more data acquisition node 142A-142C (e.g. such as whether a circuit breaker is open or closed, or tripped due to over current).

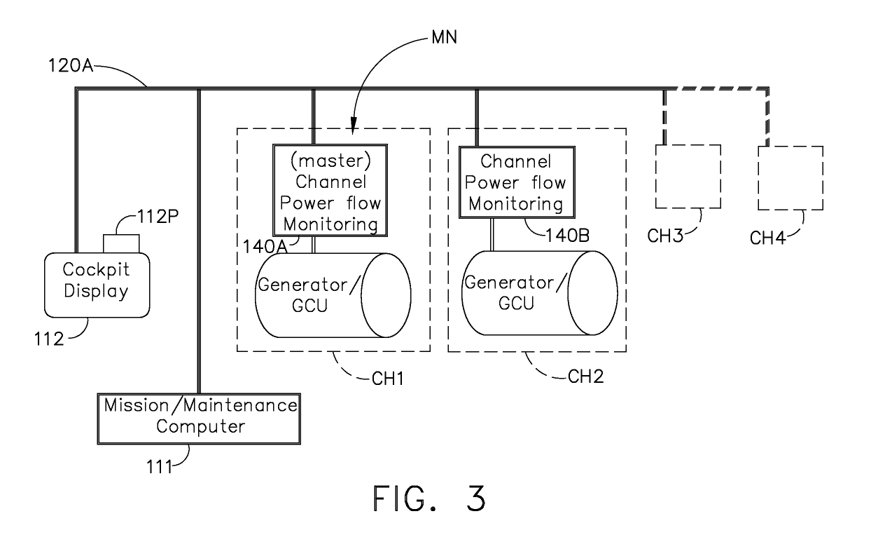

Referring also to FIG. 3, in one aspect where there are multiple channels in the vehicle electrical power system 1126, one of the channel power monitor nodes 140A-140C is configured as a master node MN that collects raw and/or processed information/data from other channel power monitor nodes 140A-140C. The master node MN is a gateway between the other channel power monitor nodes 140A-140C and, for example, the central processing computer 111. In other aspects, each channel power monitor node 140A-140C communicates respective information to the central processing computer 111 in a manner similar to that described herein with respect to the master node MN. In one aspect the master node MN further processes the raw and/or processed information from the other channel power monitor nodes 140A-140C to, for example, determine system level features and parameters related to the electrical power system 1126 of the vehicle 100. For example, the system level features and parameters include, but are not limited to, determining failures within a channel, deciphering cross-talk between channels for determining where a failure occurred, etc. The master node MN communicates the further processed information to the central processing computer 111. In other aspects the master node MN communicates the raw and/or processed information to the central processing computer without further processing such that central processing computer 111 further processes the data with respect to determining the system level features and parameters.

Referring again to FIG. 2, one channel CH1 of the vehicle electrical power system 1126 is illustrated. The channel CH1 includes one power generator 200 and a respective generator control unit (GCU) 200A, where the generator 200/generator control unit GCU are connected, through one or more power lines 290, to one or more contactor 175, one or more contactors/circuit breakers 170A-170H, one or more AC/DC convertors 171, one or more AC loads 172, one or more DC loads 173, one or more line replaceable units and/or any other suitable electronic components including, but not limited to, relays and load controllers. Each power generator 200/generator control unit GCU 200A includes, one or more suitable sensors 150, a data acquisition/memory 151 and a processor(s) 152 so as to form a respective data acquisition node 142I (i.e. the data acquisition node 142I includes power generator 200/generator control unit 200A, sensors 150, data acquisition/memory 151 and processor(s) 152). Similarly each contactor/circuit breaker 170A-170H includes one or more suitable sensors 150, a data acquisition/memory 151 and a processor(s) 152 so as to form a respective data acquisition node 142A-142E, 142F-142H. The AC/DC convertor 171 includes one or more suitable sensors 150, a data acquisition/memory 151 and a processor(s) 152 so as to form data acquisition node 142M, each of the AC loads 172 includes one or more suitable sensors 150, a data acquisition/memory 151 and a processor(s) 152 so as to form a respective data acquisition node 142K. Each DC load 173 includes one or more suitable sensors 150, a data acquisition/memory 151 and a processor(s) 152 so as to form a respective data acquisition node 142L. The electrical contactor 175 also includes one or more suitable sensors 150, a data acquisition/memory 151 and a processor(s) 152 so as to form data acquisition node 142J. As may be realized, the electrical components illustrated in FIG. 2 are exemplary only and in other aspects the vehicle electrical power system 1126 includes any other suitable number of electronic components including one or more suitable sensors 150, data acquisition/memory 151 and a processor(s) 152 so as to form any suitable number of data acquisition nodes within each channel. As an example, the data acquisition nodes 142A-142H (e.g. contactors/circuit breakers) and data acquisition node 142J (e.g. the contactor that connects the generator 200/generator control unit GCU 200A to the remainder of the channel CH1 through the power line(s) 290) are, as noted above, “smart” components that each include sensors, data acquisition/memory and processors for collecting data/information related to electrical power at a respective location within the vehicle electrical power system 1126. Each data acquisition node 142A-142H, 142J performs signal processing and calculations with respect to the electrical power and sends the raw and/or processed information, through communication link 141, to the respective channel power monitor node 140.

In one aspect individual vehicle electrical loads (e.g. such a AC and DC loads) are configured to form data acquisition nodes 142K, 142L. For example, the vehicle electrical loads may be any suitable electrical loads such as e.g. any suitable utilization equipment (including either an individual unit, set, or a complete system to which the electrical power is applied or disconnected, or both, as a whole). For example, one or more of the vehicle electrical loads (e.g. data acquisition nodes 142K, 142L) includes one or more sensor 150, data acquisition/memory 151 and a processor(s) 152 (FIG. 1) for collecting data/information related to the electrical power usage of the respective vehicle electrical load where, in one aspect, the data/information is processed at the data acquisition node 142K, 142L and communicated to the channel power monitor node 140 through communication link 141. In other aspects, the data acquisition node 142K, 142L sends raw or unprocessed data to the channel power monitor node 140 for processing.

In one aspect one or more power convertors of the vehicle electrical power system 1126 (e.g. such as the AC/DC convertor 171) form data acquisition node(s) 142M (as noted above) and are configured to communicate data/information related to the operation of the power convertor (such as current and voltage values) to the channel power monitor node 140 through the communication link 141. As may be realized, the AC/DC convertor 171 transitions AC (alternating current) power into DC (direct current) power for powering the DC loads of the vehicle 100. Similarly, the vehicle power generator(s) 200/generator control unit GCU 200A are configured to form a respective data acquisition node 142I (as described above) such that each power generator includes a generator control unit that may include a processor configured to perform protection functions, AC voltage regulation, AC system control and fault annunciation with respect to the generator 200.

As described above, the vehicle electrical power flow monitoring system 110 is a parasitic system in that the vehicle electrical power flow monitoring system 110 leverages the use (i.e. is interconnected with at least one different/preexisting vehicle monitoring systems 100DS as described above) of existing/available communication links, sensors and data in the vehicle electrical power system 1126 to take advantage of the entire vehicle system architecture to tie the different vehicle systems together into one monitoring system with a common processor to effect electrical power flow monitoring. For example, referring to FIGS. 1 and 2 at least part of the data acquisition nodes 142A-142J are, in one aspect, include components of the vehicle electrical power system 1126 (as described above) that are common to, for example, the vehicle electrical power flow monitoring system 110 described herein and at least one different/preexisting vehicle system 100DS such as a vehicle health monitoring system 110H (e.g. that is configured to communicate electrical health data associated with the vehicle electrical system 1126 to at least one vehicle health reporting system). In one aspect, as described above, each of the data acquisition nodes 142A-142J includes sensors 150, data acquisition/memory 151 and processors 152 that are components (such as smart components) of the vehicle electrical power system while in other aspects the sensors 150, data acquisition/memory 151 and processors 152 are included in the data acquisition nodes 142A-142J as components of the vehicle health monitoring system 110H or any other suitable vehicle system. In one aspect, the communication links 120A, 141A-141C and/or the channel power monitor nodes 140A-140C are also included in or are common to at least one different/preexisting vehicle system 100DS such as the vehicle health monitoring system 110H, electrical system or any other suitable vehicle system. In another aspect, one or more of the sensors 150, data acquisition 151, processors 152 and communication links 120A, 141A-141C are added to the vehicle electrical power system 1126 components as necessary such that the sensors 150, data acquisition 151, processors 152 and communication links 120A, 141A-141C are shared between any suitable vehicle monitoring and/or control systems (e.g. with respect to monitoring vehicle performance, maintenance, etc.).

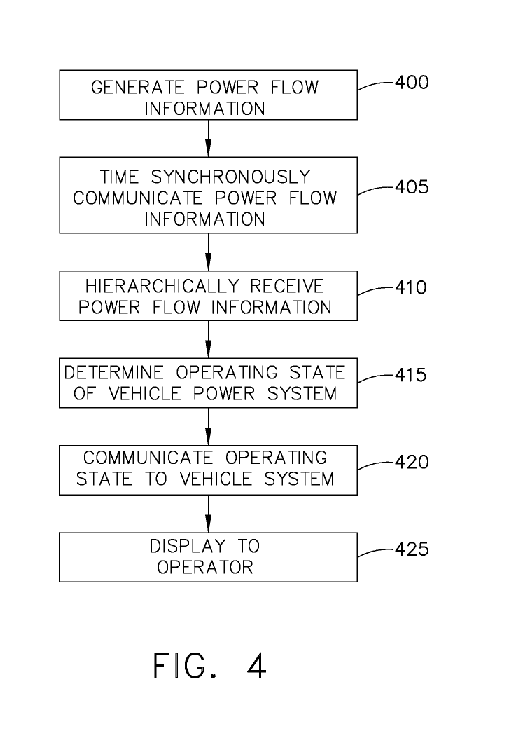

In one aspect the power flow monitoring system and the different/preexisting vehicle system (e.g. such as the health monitoring system 110H) share a distributed system architecture where, for example, the channel power monitor nodes 140A-140C and data acquisition nodes 142A-142J are shared between or are common to both the different/preexisting vehicle system 100DS and the vehicle electrical power flow monitoring system 110 so as to tie the two systems together into a common monitoring system with a common processor for power flow monitoring. As noted herein, each of the distributed data acquisition nodes 142A-142M processes data from a corresponding vehicle electrical power system component to generate power flow information (FIG. 4, Block 400, where FIG. 4 illustrates a method for monitoring electrical power flow within a vehicle). For example, a data acquisition node 142A-142M monitors and processes data associated with a respective vehicle electrical system 1126 component (e.g., a contactor, a relay, a load controller, a load, or a power source) to determine a power flow value (e.g., such as those described above) of the respective vehicle electrical system 1126 component. Each of the one or more data acquisition nodes 142A-142M time synchronously communicates the power flow information (i.e. the power flow information is time stamped according to a common clock signal common to all components of the vehicle 100) to a respective channel power monitor node 140A-140C via a respective communication link 141A-141C (FIG. 4, Block 405). As may be realized, the distributed vehicle electrical power flow monitoring system 110 architecture is independent of a type of hardware used for communication between the nodes. The channel power monitor node 140A-140C receives the power flow information from associated data acquisition nodes 142A-142M that are associated with one or more distribution circuit components of the vehicle electrical power system 1126 (FIG. 4, Block 410). The channel power monitor mode 140A-140C processes the power flow information with any suitable algorithm(s) resident therein to determine an operating state(s) of at least a portion (e.g. a particular component of the vehicle electrical power system 1126, a channel of the vehicle electrical power system, the overall electrical power system etc.) of the vehicle electrical power system 1126 (FIG. 4, Block 415). The operating states of the vehicle electrical power system 1126 include, but are not limited to, for example, an active/operable state, an inactive/inoperable state, fault conditions, which sources or power conversion devices are energized, not energized or failed, a state of a system contactor (open/closed/failed), which electrical loads are being powered, which electrical loads are not being powered and if they were commanded off or was a protective function engaged, which electrical buses are connected to which power source, were any protective functions engaged that resulted in bus transfers or busses being de-energized, etc. The channel power monitor node 140A-140C communicates the operating state(s) to one or more vehicle systems, such as central processing computer 111 through, for example, the communication link 120A or in other aspects to one or more off vehicle (or otherwise ground based) monitor/maintenance locations through communication link 120B (FIG. 4, Block 420) for displaying to an operator of the vehicle 100 (FIG. 4, Block 425). In one aspect, the data acquisition nodes 142A-141M and the channel power monitor nodes 140A-140B are time synchronized to provide time stamped power flow data for diagnostic and/or prognostic analysis.

In one aspect the algorithm(s) in each channel power monitor node 140A-140C calculates an amount of power that flows to each load (e.g. the AC loads and the DC loads) based on the current that is measured at each load. The algorithm is configured to calculate a sum of reactive and real powers to each load and provide a resultant as the total power flowing through each channel CH1, CH2, CH3.

In other aspects, the algorithm(s) of each channel power monitor node 140A-140C is configured to calculate an amount of power that flows to each power bus of the vehicle electrical power system 1126 and each load (e.g. AC loads and DC loads) based on, for example, currents and voltages measured at one or more of the data acquisition nodes 142A-142M and/or at each load (e.g. AC loads and DC loads). Here the algorithm(s) calculates a sum of the powers to each load and at various data acquisition nodes 142A-142M within the vehicle electrical power system 1126. For AC powered loads, a vector sum of the reactive and real powers is used to calculate the apparent power values. For DC powered loads the real power measurements are used. The calculated and measured load values are used by, for example, the respective channel power monitor node 140A-140B or the master channel power monitor node MN (FIG. 3) for calculating the total power flow through each channel CH1, CH2, CH3.

The vehicle electrical power system 1126 state information, as described above, is presented to an operator of the vehicle through, for example, the display 112 in any suitable manner, such as in the form of a system diagram (which in one aspect is similar to the system diagram illustrated in FIG. 2 with the addition of each AC and DC load being illustrated) showing connections between active power sources and the busses/loads that the active power sources supply. The calculated or measured power flowing from each power source and to each bus/load is displayed in the system diagram to indicate, for example, overloading conditions, which then prompts operator action or automated action such as load shedding by the central processing computer 111 or any other suitable controller of the vehicle 100.

Processing of data in a distributed networked system architecture (e.g., at each data acquisition node and each channel power monitor node at a location from which the data was obtained) enables diagnostic analysis of the electrical power system with a high level of fault detection, isolation, and localization as well as decreases network data traffic as the power flow data is processed, at least in part, at a point of the network from which the data originated. As may be realized, accurately pinpointing a failure in the vehicle electrical system 1126 reduces troubleshooting time and increases availability of the vehicle 100. The distributed network system architecture enables the channel power monitor nodes 140A-140C to utilize the voltage and current measurements as well as other suitable data (as described herein) from the data acquisition nodes 142A-142M for one or more of diagnostics and prognostics. In the aspects of the disclosure the power flow characteristics of the vehicle electrical power system 1126 are monitored in real time at a source of the characteristic being monitored. For example, current and voltage (and other characteristics) of the generator line contactor (e.g. data acquisition node 142J) is monitored in real time by sensors/processor located at the generator line contactor. Similarly, power flow characteristics within the power distribution channel CH1, CH2, CH3 are monitored at the various contactors/circuit breakers (e.g. data acquisition nodes 142A-142G), at the electrical loads (e.g. data acquisition nodes 142K, 142L), at the AC/DC convertor(s) (e.g. data acquisition node 142M) and/or at any other suitable component of the vehicle electrical system by sensors/processor located at respective ones of the vehicle electrical system components.

The disclosure and drawing figures describing the operations of the method(s) set forth herein should not be interpreted as necessarily determining a sequence in which the operations are to be performed. Rather, although one illustrative order is indicated, it is to be understood that the sequence of the operations may be modified when appropriate. Accordingly, certain operations may be performed in a different order or simultaneously. Additionally, in some aspects of the disclosure, not all operations described herein need be performed.

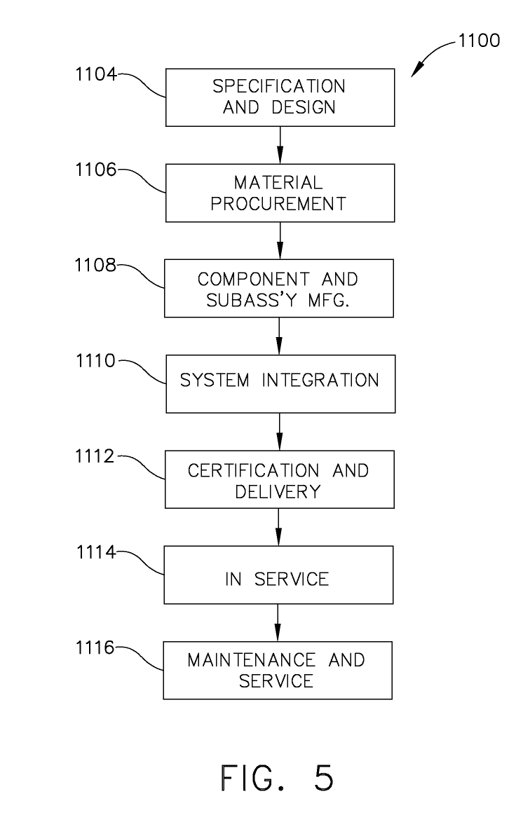

Examples of the disclosure may be described in the context of an aircraft manufacturing and service method 1100 as shown in FIG. 5 and an aircraft 1102 as shown in FIG. 6. During pre-production, illustrative method 1100 may include specification and design 1104 of the aircraft 1102 and material procurement 1106. During production, component and subassembly manufacturing 1108 and system integration 1110 of the aircraft 1102 take place. Thereafter, the aircraft 1102 may go through certification and delivery 1112 to be placed in service 1114. While in service by a customer, the aircraft 1102 is scheduled for routine maintenance and service 1116 (which may also include modification, reconfiguration, refurbishment, and so on).

Each of the processes of the illustrative method 1100 may be performed or carried out by a system integrator, a third party, and/or an operator (e.g., a customer). For the purposes of this description, a system integrator may include, without limitation, any number of aircraft manufacturers and major-system subcontractors; a third party may include, without limitation, any number of vendors, subcontractors, and suppliers; and an operator may be an airline, leasing company, military entity, service organization, and so on.

As shown in FIG. 6, the aircraft 1102 produced by the illustrative method 100 may include an airframe 1118 with a plurality of high-level systems and an interior 1122. Examples of high-level systems, which are distributed throughout the aircraft, include one or more of a propulsion system 1124, an electrical power system 1126, a hydraulic system 1128, and an environmental system 1130. Any number of other systems may be included. Although an aerospace example is shown, the principles of the invention may be applied to other industries, such as the automotive industry.

Apparatus and methods shown or described herein may be employed during any one or more of the stages of the manufacturing and service method 1100. For example, components or subassemblies corresponding to component and subassembly manufacturing 1108 may be fabricated or manufactured in a manner similar to components or subassemblies produced while the aircraft 1102 is in service. Also, one or more aspects of the apparatus, method, or combination thereof may be utilized during the production states 1108 and 1110, for example, by substantially expediting assembly of or reducing the cost of an aircraft 1102. Similarly, one or more aspects of the apparatus or method realizations, or a combination thereof, may be utilized, for example and without limitation, while the aircraft 1102 is in service, e.g., operation, maintenance and service 1116.

Different examples and aspects of the apparatus and methods are disclosed herein that include a variety of components, features, and functionality. It should be understood that the various examples and aspects of the apparatus and methods disclosed herein may include any of the components, features, and functionality of any of the other examples and aspects of the apparatus and methods disclosed herein in any combination, and all of such possibilities are intended to be within the spirit and scope of the present disclosure.

Many modifications and other examples of the disclosure set forth herein will come to mind to one skilled in the art to which the disclosure pertains having the benefit of the teachings presented in the foregoing descriptions and the associated drawings.

In one or more aspects of the present disclosure a vehicle electrical power flow monitoring system includes at least one channel power monitor node corresponding to a respective power distribution channel of a vehicle electrical power system, the at least one channel power monitor node being common to at least another different vehicle monitoring system, and at least one data acquisition node within each power distribution channel, each of the at least one data acquisition node being common to the at least another different vehicle monitoring system and communicably connected to a respective channel power monitor node; and wherein the at least one channel power monitor node is configured to receive electrical power flow data from a corresponding data acquisition node and determine an operating state of the vehicle electrical power system based on the electrical power flow data.

In one or more aspects of the present disclosure the vehicle electrical power flow monitoring system further includes at least one of a wired or wireless serial communication link connecting the at least one data acquisition node to a respective channel power monitor node.

In one or more aspects of the present disclosure the at least one channel power monitor node comprises a master channel monitor node configured to receive and process data from other ones of the at least one channel power monitor node.

In one or more aspects of the present disclosure the at least one data acquisition node comprises an electrical component of the vehicle electrical power system.

In one or more aspects of the present disclosure the vehicle electrical power flow monitoring system further includes a central procession computer connected to the at least one channel power monitor node, the central processing computer being configured to receive and process data from the at least one channel power monitor node for presentation to at least an operator of the vehicle.

In one or more aspects of the present disclosure each of the data acquisition nodes includes a processor configured to process electrical power flow data obtained from a respective component of the vehicle electrical power system at a location of the respective component so that processed electrical power flow data is sent to the respective channel power monitor node.

In one or more aspects of the present disclosure the electrical power flow data is time synchronous data.

In one or aspects of the present disclosure, the channel power monitor node synchronizes its time with aircraft time.

In one or more aspects of the present disclosure the vehicle comprises an aerospace, maritime, or ground based vehicle, or electrical power distribution network.

In one or more aspects of the present disclosure a vehicle electrical power flow monitoring system includes a user interface, a parasitic power flow monitor having a hierarchical architecture and including at least one channel power monitor node corresponding to a respective power distribution channel of a vehicle electrical power system, the at least one channel power monitor node being common to at least another different vehicle monitoring system, and a plurality of acquisition nodes within each power distribution channel, each of the plurality of data acquisition nodes being common to the at least another different vehicle monitoring system and communicably connected to a corresponding channel power monitor node, and wherein the at least one channel power monitor node is configured to receive electrical power flow data from respective ones of the at least one data acquisition node and determine an operating state of the vehicle electrical power system based on the electrical power flow data.

In one or more aspects of the present disclosure the vehicle electrical power flow monitoring system further includes at least one serial communication bus connecting the plurality of data acquisition nodes to a respective channel power monitor node and connecting the user interface to the at least one channel power monitor node.

In one or more aspects of the present disclosure the at least one channel power monitor node comprises a master channel monitor node configured to receive and process data from other ones of the at least one channel power monitor node, the master channel monitor node being configured as a gateway for communication between other channel power monitor nodes and the user interface.

In one or more aspects of the present disclosure the master channel monitor node provides power flow information to an operator via one or more of a display processor and a central processing computer

In one or more aspects of the present disclosure each data acquisition node comprises an electrical component of the vehicle electrical power system.

In one or more aspects of the present disclosure the user interface comprises a display connected to the at least one channel power monitor node, via one or more of a display processor and a central processing computer, the one or more of the central processing computer and the display processor being configured to receive and process data from the at least one channel power monitor node for presentation to at least an operator of the vehicle.

In one or more aspects of the present disclosure each of the data acquisition nodes includes a processor configured to process electrical power flow data obtained from sensors installed on a respective component of the vehicle electrical power system at a location of the respective component so that processed electrical power flow data is sent to the respective channel power monitor node.

In one or more aspects of the present disclosure the electrical power flow data is time synchronous data.

In one or more aspects of the present disclosure a method includes sending electrical power flow data from at least one data acquisition node, that is common to a plurality of vehicle monitoring systems, distributed throughout a power distribution channel of an electrical power system of a vehicle, to a respective channel power monitor node that is common to a plurality of vehicle monitoring systems, and determining, with at least one channel power monitor node, an operating state of the electrical power system based on the electrical power flow data.

In one or more aspects of the present disclosure the electrical power flow data is time synchronous data.

In one or more aspects of the present disclosure the method further includes connecting the at least one data acquisition node to the respective channel power monitor node with at least one serial communication bus that is a common to the plurality of vehicle monitoring systems.

In one or more aspects of the present disclosure the method further includes receiving and processing data from the respective channel power monitor node with one or more of a display processor and a central processing computer, connected to the respective channel power monitor node, for presentation to at least an operator of a vehicle.

In one or more aspects of the present disclosure the method further includes processing, with each data acquisition node, electrical power flow data obtained from a respective component of the electrical power system at a location of the respective component so that processed electrical power flow data is sent to the respective channel power monitor node.

In or more aspects of the present disclosure the method further includes processing the method further includes synchronizing a time of the channel power monitor node with a vehicle time via a central processing computer or via a global positioning system of the vehicle.

In or more aspects of the present disclosure the method further includes processing the method further includes receiving, with the channel power monitor node, the vehicle time from the central processing computer via serial link and adjusting a time of the channel power monitor node periodically to be synchronized with the vehicle time.

Therefore, it is to be understood that the disclosure is not to be limited to the specific embodiments disclosed and that modifications and other embodiments are intended to be included within the scope of the appended claims. Moreover, although the foregoing descriptions and the associated drawings describe example embodiments in the context of certain illustrative combinations of elements and/or functions, it should be appreciated that different combinations of elements and/or functions may be provided by alternative implementations without departing from the scope of the appended claims.

What is claimed is:

1. A vehicle electrical power flow monitoring system comprising:
at least one channel power monitor node corresponding to a respective power distribution channel of a vehicle electrical power system, the at least one channel power monitor node being common to at least another different vehicle monitoring system, and
at least one data acquisition node within each power distribution channel, each of the at least one data acquisition node being common to the at least another different vehicle monitoring system and communicably connected to a respective channel power monitor node; and
wherein the at least one channel power monitor node is configured to receive electrical power flow data from a corresponding data acquisition node and determine an operating state of the vehicle electrical power system based on the electrical power flow data.

2. The vehicle electrical power flow monitoring system of claim 1, further comprising at least one of a wired or wireless serial communication link connecting the at least one data acquisition node to a respective channel power monitor node.

3. The vehicle electrical power flow monitoring system of claim 1, wherein the at least one channel power monitor node comprises a master channel monitor node configured to receive and process data from other ones of the at least one channel power monitor node.

4. The vehicle electrical power flow monitoring system of claim 1, wherein the at least one data acquisition node comprises an electrical component of the vehicle electrical power system.

5. The vehicle electrical power flow monitoring system of claim 1, further comprising a central processing computer connected to the at least one channel power monitor node, the central processing computer being configured to receive and process data from the at least one channel power monitor node for presentation to at least an operator of the vehicle.

6. The vehicle electrical power flow monitoring system of claim 1, wherein each of the data acquisition nodes includes a processor configured to process electrical power flow data obtained from a respective component of the vehicle electrical power system at a location of the respective component so that processed electrical power flow data is sent to the respective channel power monitor node.

7. A vehicle electrical power flow monitoring system comprising:
a user interface;
a parasitic power flow monitor having a hierarchical architecture and including
at least one channel power monitor node corresponding to a respective power distribution channel of a vehicle electrical power system, the at least one channel power monitor node being common to at least another different vehicle monitoring system, and
a plurality of acquisition nodes within each power distribution channel, each of the plurality of data acquisition nodes being common to the at least another different vehicle monitoring system and communicably connected to a corresponding channel power monitor node; and
wherein the at least one channel power monitor node is configured to receive electrical power flow data from respective ones of the at least one data acquisition node and determine an operating state of the vehicle electrical power system based on the electrical power flow data.

8. The vehicle electrical power flow monitoring system of claim 7, further comprising at least one serial communication bus connecting the plurality of data acquisition nodes to a respective channel power monitor node and connecting the user interface to the at least one channel power monitor node.

9. The vehicle electrical power flow monitoring system of claim 7, wherein the at least one channel power monitor node comprises a master channel monitor node configured to receive and process data from other ones of the at least one channel power monitor node, the master channel monitor node being configured as a gateway for communication between other channel power monitor nodes and the user interface.

10. The vehicle electrical power flow monitoring system of claim 7, wherein the master channel monitor node provides power flow information to an operator via one or more of a display processor and a central processing computer

11. The vehicle electrical power flow monitoring system of claim 7, wherein each data acquisition node comprises an electrical component of the vehicle electrical power system.

12. The vehicle electrical power flow monitoring system of claim 7, wherein the user interface comprises a display connected to the at least one channel power monitor node, via one or more of a display processor and a central processing computer, the one or more of the central processing computer and the display processor being configured to receive and process data from the at least one channel power monitor node for presentation to at least an operator of the vehicle.

13. The vehicle electrical power flow monitoring system of claim 7, wherein each of the data acquisition nodes includes a processor configured to process electrical power flow data obtained from sensors installed on a respective component of the vehicle electrical power system at a location of the respective component so that processed electrical power flow data is sent to the respective channel power monitor node.

14. A method comprising:
sending electrical power flow data from at least one data acquisition node, that is common to a plurality of vehicle monitoring systems, distributed throughout a power distribution channel of an electrical power system of a vehicle, to a respective channel power monitor node that is common to a plurality of vehicle monitoring systems; and
determining, with at least one channel power monitor node, an operating state of the electrical power system based on the electrical power flow data.

15. The method of claim 14, wherein the electrical power flow data is time synchronous data.

16. The method of claim 14, further comprising connecting the at least one data acquisition node to the respective channel power monitor node with at least one serial communication bus that is a common to the plurality of vehicle monitoring systems.

17. The method of claim 14, further comprising receiving and processing data from the respective channel power monitor node with one or more of a display processor and a central processing computer, connected to the respective channel power monitor node, for presentation to at least an operator of a vehicle.

18. The method of claim 14, further comprising processing, with each data acquisition node, electrical power flow data obtained from a respective component of the electrical power system at a location of the respective component so that processed electrical power flow data is sent to the respective channel power monitor node.

19. The method of claim 14, further comprising synchronizing a time of the channel power monitor node with a vehicle time via a central processing computer or via a global positioning system of the vehicle.

20. The method of claim 14, further comprising receiving, with the channel power monitor node, the vehicle time from the central processing computer via serial link and adjusting a time of the channel power monitor node periodically to be synchronized with the vehicle time.
